(19) United States
(12) Patent Application Publication
(10) Pub. No.: US 2005/0012087 A1
(43) Pub. Date: Jan. 20, 2005

(54) Self-aligned MOSFET having an oxide region below the channel

(76) Inventors: Yi-Ming Sheu, Hsin-Chu (TW); Chung-Cheng Wu, Hsin-Chu (TW)

Correspondence Address: SLATER & MATSIL, L.L.P., 17950 PRESTON ROAD, SUITE 1000, DALLAS, TX, 75252, US

(21) Appl. No.: 10/619,828

(22) Filed: Jul. 15, 2003

(51) Int. Cl. H01L 29/06

(52) U.S. Cl. 257/14

(57) ABSTRACT

A transistor device having a strained channel and a method for forming the transistor device are disclosed. The transistor device includes a semiconductor region having a top surface. The transistor device includes a source region, a drain region, and a channel region in the semiconductor region. The channel region is between the source region and the drain region. The transistor device includes an oxide region within the channel region and a gate overlying the channel region. The oxide region is laterally spaced from the source and drain regions. The transistor device includes a gate dielectric between the gate and the channel region.

### TECHNICAL FIELD

The present invention relates generally to integrated circuits, and more particularly to a self-aligned MOSFET with an oxide region in the channel, preferably forming a strained channel region.

### BACKGROUND

Complementary metal-oxide-semiconductor (CMOS) technology is the dominant semiconductor technology used for the manufacture of ultra-large scale integrated (ULSI) circuits today. A CMOS device generally includes metal-oxide-semiconductor field-effect transistors (MOSFETs).

FIG. 1 shows that a conventional CMOS device 100 includes an N-channel MOSFET 120 and a P-channel MOSFET 130. MOSFET 120 and MOSFET 130 can be isolated from each other by oxide isolations 110. MOSFET 120 includes source and drain regions, 121 and 122. MOSFET 120 also includes a gate 123 overlying a channel region 125. Gate 123 and channel region 125 are separated from each other by a gate dielectric 124. P-channel MOSFET 130 includes source and drain regions, 131 and 132. MOSFET 130 also includes a gate 133 overlying a channel region 135. Gate 133 and channel region 135 are separated from each other by a gate dielectric 134.

Size reduction of the metal-oxide-semiconductor field-effect transistor (MOSFET) has provided significant improvement in the speed performance, circuit density, and cost per unit function of semiconductor chips over the past few decades. Significant challenges are faced when CMOS devices are scaled into the sub-100 nm regime. An attractive approach for additional improvement of CMOS transistor performance exploits strain-induced band-structure modification and mobility enhancement to increase the transistor drive current. Enhanced electron and hole mobilities improve the drive currents of N-channel and P-channel MOSFETs, respectively.

### SUMMARY OF THE INVENTION

The present invention describes embodiments of an improved method of fabricating a self-aligned MOSFET with an impurity region formed within the channel.

In one aspect, the present invention provides for a transistor device. The transistor device includes a semiconductor region having a top surface. The transistor device also includes a source region, a drain region, and a channel region in the semiconductor region. The channel region is between the source region and the drain region. The transistor device includes an oxide region within the channel region and a gate overlying the channel region. The oxide region is laterally spaced from the source and drain regions. The transistor device includes a gate dielectric between the gate and the channel region.

With the preferred methods, a method of forming a transistor device includes providing a semiconductor region having a top surface. The method includes forming source and drain regions in a semiconductor region. The source region is spaced from the drain region by a channel region. The method includes forming an oxide region within the channel region and spaced from the top surface. The method also includes forming a gate overlying and insulated from the channel region.

With the preferred methods, one or more of the following advantages can be realized. Electron mobilities in N-channel MOSFETs can be enhanced, and drive currents of N-channel MOSFETs can be improved. Hole mobilities in P-channel MOSFETs can be enhanced, and drive currents of P-channel MOSFETs can be improved. The oxide region in the channel region can also reduce the probability of shorting the channel. Additionally, the source to drain resistance of a self-aligned MOSFET having a strained channel is generally smaller than that of an SOI MOSFET.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a conventional CMOS device including a P-channel MOSFET and an N-channel MOSFET;

FIG. 2 shows a CMOS device that includes at least one self-aligned MOSFET with a strained channel on top of an oxide region;

FIGS. 3a through 3o show various steps in the manufacture of a CMOS device employing advantageous features of the preferred embodiments of the present invention; and

FIGS. 4a and 4b illustrate alternative embodiment CMOS devices having an oxide region in only one channel of the respective transistors.

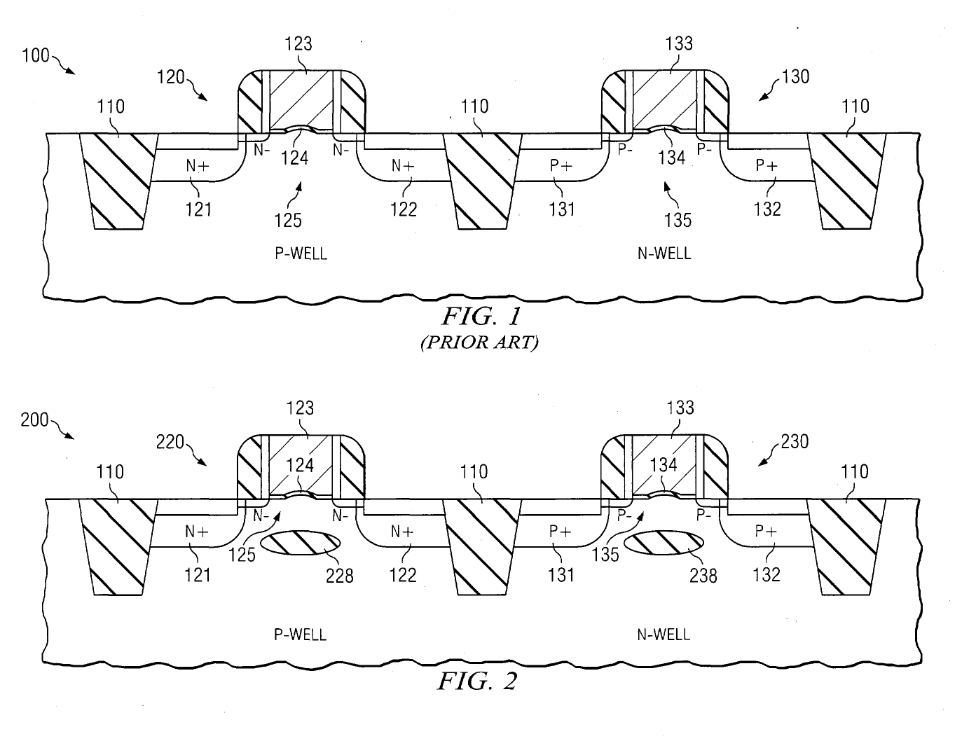

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

FIG. 2 shows a CMOS device 200 that includes at least one self-aligned MOSFET with a strained channel on top of an oxide region. As an example, CMOS device 200 in FIG. 2 includes two self-aligned MOSFETs, preferably with strained channels: an N-channel MOSFET 220 and a P-channel MOSFET 230. N-channel MOSFET 220 and P-channel MOSFET 230 can be isolated from each other by isolation regions 110. In the illustrated embodiment, trench isolation is used. Other isolation techniques, such as field isolation, can also be employed.

N-channel MOSFET 220 includes source and drain regions, 121 and 122. N-channel MOSFET 120 also includes a gate 123 overlying a channel region 125. Channel region 125 is between source and drain regions, 121 and 122. Gate 123 and channel region 125 are separated from each other by a gate dielectric 124. In addition, P-channel MOSFET 220 includes an oxide region 228 within channel region 125. Oxide region 228 is laterally spaced from source and drain regions, 121 and 122. The region between oxide region 228 and gate 123 is preferably a strained channel. When a channel in N-channel MOSFET 220 is strained, hole mobilities in the strained channel generally are enhanced. Drive currents of N-channel MOSFET 220 are generally increased as well. Although it is currently believed that the strain imposed on the channel is the cause of the improved performance of the preferred embodiment devices, the scope of the present invention should not be limited to any particular mechanism or theory.

P-channel MOSFET 230 includes source and drain regions, 131 and 132. P-channel MOSFET 230 also includes a gate 133 overlying a channel region 135. Channel region 135 is between source and drain regions, 131 and 132. Gate 133 and channel region 135 are separated from each other by a gate dielectric 134. In addition, P-channel MOSFET 230 includes an oxide region 238 within channel region 135. Oxide region 238 is laterally spaced from source and drain regions, 131 and 132. The region between oxide region 238 and gate 133 preferably defines a strained channel. When the channel in P-channel MOSFET 230 is strained, electron mobilities in the strained channel generally are enhanced. Drive currents of P-channel MOSFET 230 are generally increased as well.

N-channel MOSFET 220 with a strained channel has some structures similar to a conventional N-channel MOSFET 120, and P-channel MOSFET 230 with a strained channel has some structures similar to a conventional P-channel MOSFET 130. Thus, many conventional methods for manufacturing conventional N-channel MOSFET 120 can be modified for manufacturing N-channel MOSFET 220 with a strained channel, and many conventional methods for manufacturing conventional P-channel MOSFET 130 can be modified for manufacturing P-channel MOSFET 230 with a strained channel. Furthermore, many conventional methods for manufacturing conventional CMOS device 100 can be modified for manufacturing CMOS device 200 that includes at least one self-aligned MOSFET with a strained channel.

In general, a method for forming a conventional MOSFET includes the steps of forming source and drain regions to define a channel region between the source and drain regions, and forming a gate overlying and insulated from the channel region, although not necessarily in this order. These steps are also included in a method for forming a MOSFET having a strained channel. The method for forming a MOSFET having a strained channel, however, includes the additional step of forming an oxide region spaced from the top surface and within (or below) the channel region.

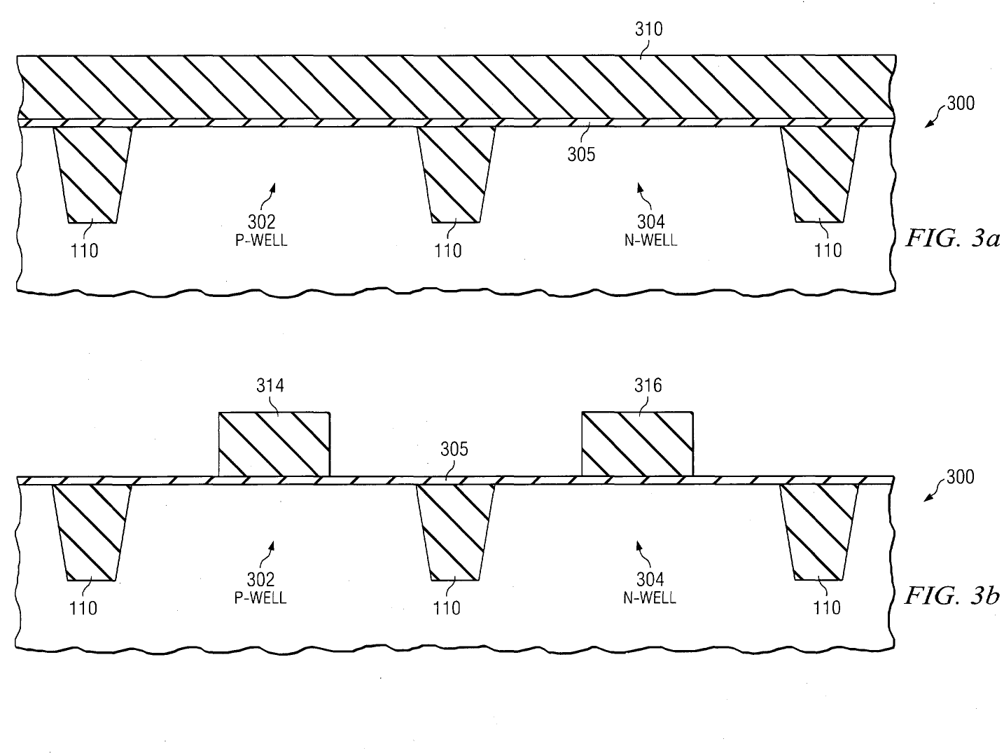

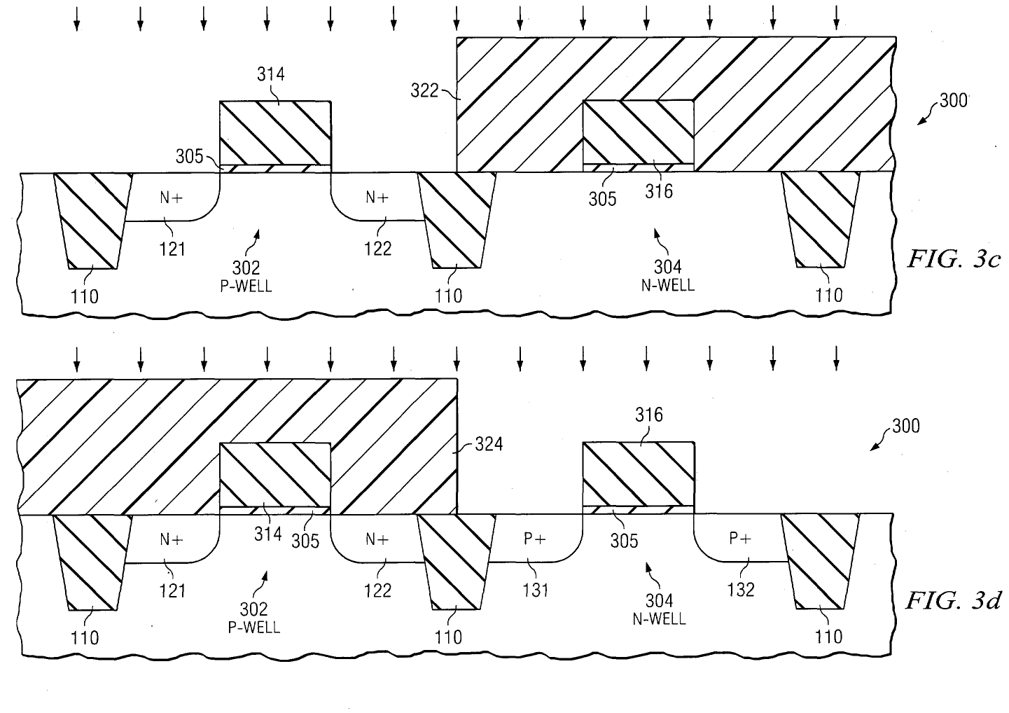

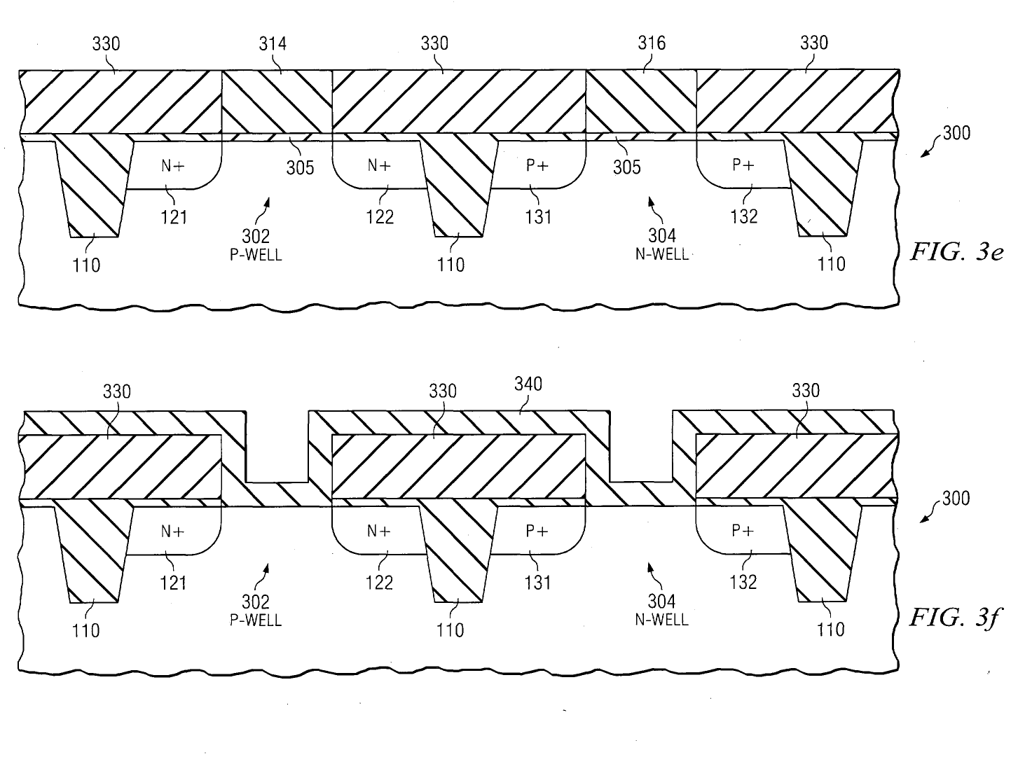

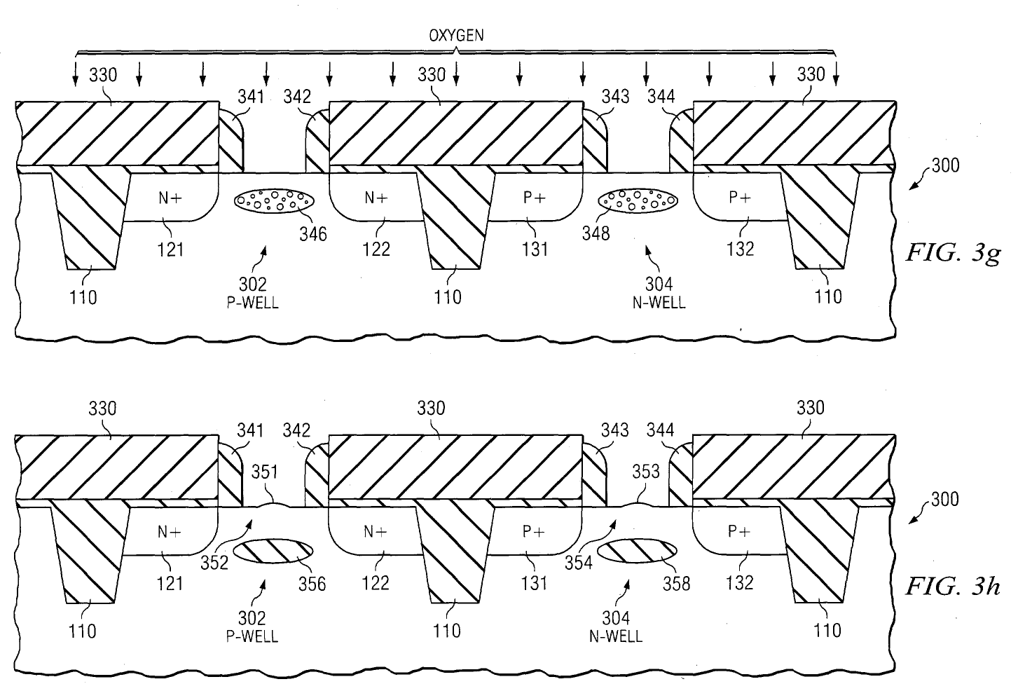

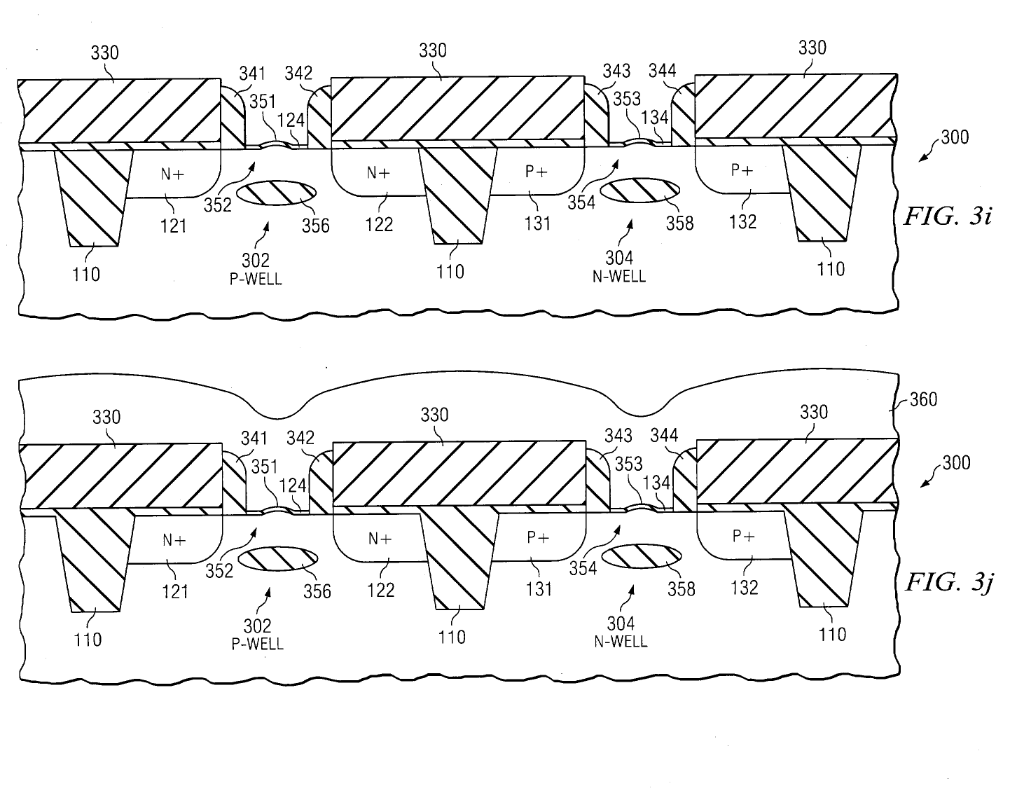

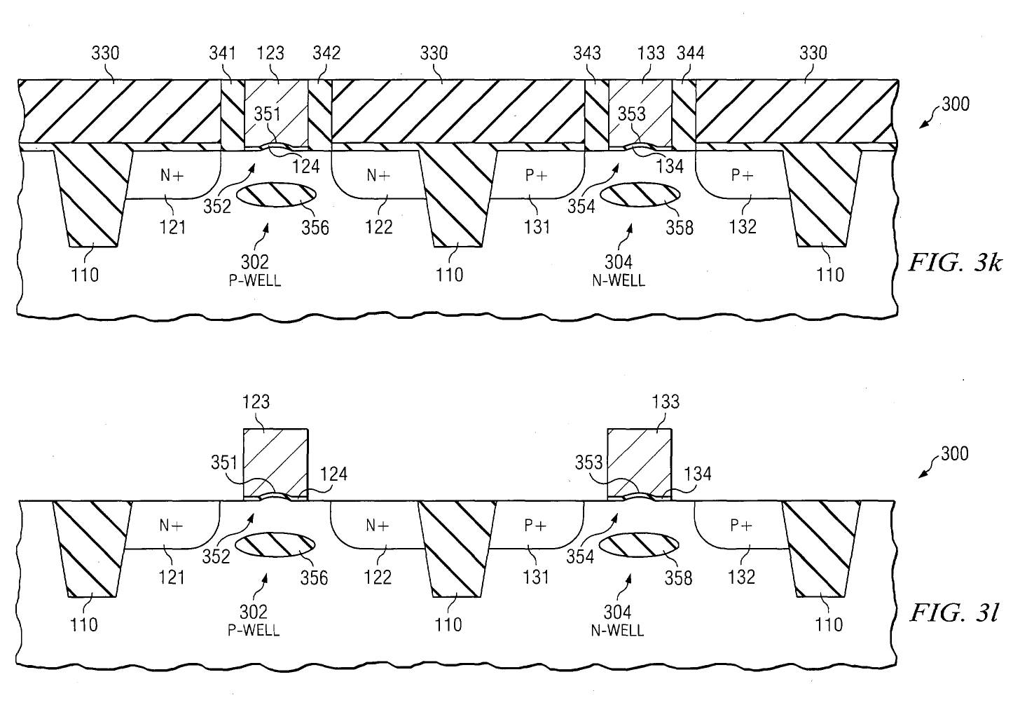

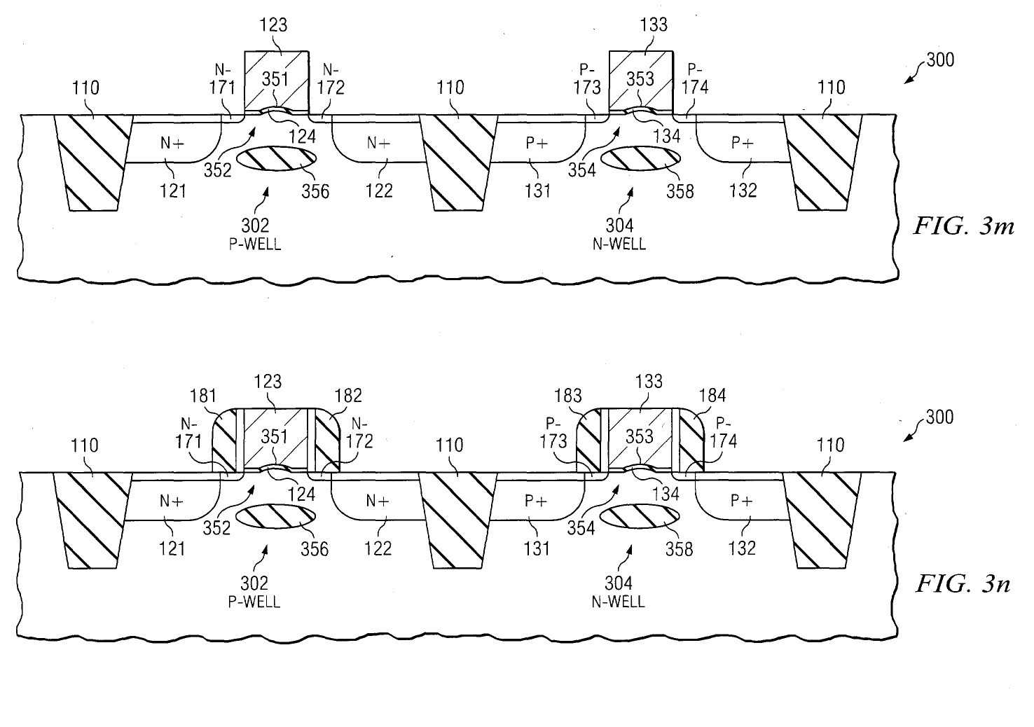

As an example, FIGS. 3a-3o show a manufacturing process for forming a CMOS device 200 that includes two self-aligned MOSFETs with strained channels. FIGS. 3a-3o sequentially depict a preferred manufacturing process. Each figure generally depicts one or more steps in the manufacturing process, although the present invention is not limited to the preferred sequence of steps described herein.

FIG. 3a shows that oxide isolation regions 10 are formed in a silicon substrate 300. Oxide isolation regions 110 can be in the form of shallow trench isolations or in the form of field oxides. Field oxides can be formed using some well-known processes, such as local oxidation of silicon. Oxide isolation regions 110 are used to define a semiconductor region 302 for an N-channel MOSFET and a semiconductor region 304 for a P-channel MOSFET. P-well semiconductor regions 302 and N-well semiconductor regions 304 are preferably formed by introducing impurities of the appropriate conductivity type into substrate 300 as is well known in the art. In FIG. 3a, a layer of SiON 305 is formed on top of silicon substrate 300, and a layer of oxide 310 is formed on top of SiON 305.

FIG. 3b shows that channel masks 314 and 316 are formed on top of silicon substrate 300. Channel masks 314 and 316 are preferably hard masks formed by defining patterns on top of the oxide layer 310 using photolithography techniques and etching away some selected areas in the oxide layer 310. After formation of channel masks 314 and 316, SiON layer 305 is removed from the exposed substrate surface, preferably using conventional etch techniques, and remains only beneath channel masks 314 and 316 as illustrated in FIG. 3c.

FIG. 3c shows that source and drain regions 121 and 122, for an N-channel MOSFET, are formed in semiconductor region 302. Source and drain regions 121 and 122 can be formed by heavily doping selected areas with n-type dopant using some well-known techniques, such as ion implantation. During the process of forming source and drain regions 121 and 122, for an N-channel MOSFET, semiconductor region 304 for a P-channel MOSFET is usually protected by covering the region with photoresist 322.

FIG. 3d shows that source and drain regions 131 and 132, for a P-channel MOSFET, are formed in semiconductor region 304. Source and drain regions 131 and 132 can be formed by heavily doping selected areas with p-type dopant using some well-known techniques, such as ion implantation. During the process of forming source and drain regions 131 and 132, for a P-channel MOSFET, semiconductor region 302 for an N-channel MOSFET is usually protected by covering the region with photoresist 324.

After formation of the source and drain regions, a silicon nitride layer 330 is formed, as shown in FIG. 3e. Silicon nitride layer 330 is preferably formed in two steps. In the first step, a layer of silicon nitride is deposited on top of silicon substrate 300. The silicon nitride layer covers the areas between the channel masks. The layer of silicon nitride can also cover the top of channel masks (314 and 316). In the second step, a chemical mechanical polishing (“CMP”) process is preferably used to form a flat surface that includes the surface of channel masks 314 and 316 and the surface of silicon nitride layer 330.

Because the surface of channel masks 314 and 316 is exposed, channel masks 314 and 316 can be selectively etched away using a selective etching process. During the selective etching process, the etching rate on silicon oxide (or silicon dioxide) is significantly higher than the etching rate on silicon nitride.

FIG. 3f shows that a conformal oxide layer 340 is deposited on top of silicon substrate 300. Conformal oxide layer 340 is deposited after channel masks 314 and 316 have been removed. Conformal oxide layer 340 covers the exposed surfaces of silicon nitride layer 330 and other exposed surfaces on top of silicon substrate 300.

FIG. 3g shows that pockets of oxygen 346 and 348 are created, respectively, in semiconductor regions 302 and 304. Pockets of oxygen 346 and 348 can be created by, e.g., an ion implantation process. During the ion implantation process, energies and dosages of oxygen ions can be adjusted to optimize the oxygen profiles in pockets 346 and 348. Preferably, the oxygen ions are implanted at an energy of from 50 to 500 keV, more preferably at about 300 keV. Typically, the ions are implanted to a concentration of from about 5×10¹⁵ cm⁻² to about 5×10^{≠}cm⁻² and in the presently contemplated preferred embodiments to a concentration of about 2×10¹⁶ cm⁻². In other embodiments, nitride ions could be implanted in the silicon region to form a silicon nitride pocket. Yet other impurities could also be employed under the teachings provided herein. Before the ion implantation process, oxide spacers 341 and 342 near semiconductor region 302 and oxide spacers 343 and 344 near semiconductor region 304 can be formed by an anisotropic etching process (e.g., a reactive ion etching process of oxide 340). Although oxide spacers 341, 342, 343, and 344 are employed in conventional CMOS fabrication and are illustrated to demonstrate compatibility of the present invention with standard processes, the spacers are not necessary for practice of the invention.

In the presently contemplated embodiments, oxygen pockets 346 and 348 will typically be formed at a depth of roughly 100 to 1000 Angstroms below the substrate surface and preferably at about 500 Angstroms. One skilled in the art will recognize that the depth of the pockets is dependent upon many parameters, particularly the depth and size of other transistor components. As an example, advantageous features of the present invention may be realized when the oxygen pockets are formed to a depth intermediate the depth of the lightly doped drain regions and the source/drain regions.

FIG. 3h shows that oxide regions 356 and 358 are formed, respectively, in semiconductor regions 302 and 304 after CMOS device 200 is subjected to an annealing process. During the annealing process, pockets of oxygen 346 and 348 change into, respectively, oxide regions 356 and 358. The formation of oxide region 356 creates a stressed channel 352 between a top surface 351 and oxide region 356. The formation of oxide region 358 creates a stressed channel 354 between a top surface 353 and oxide region 358.

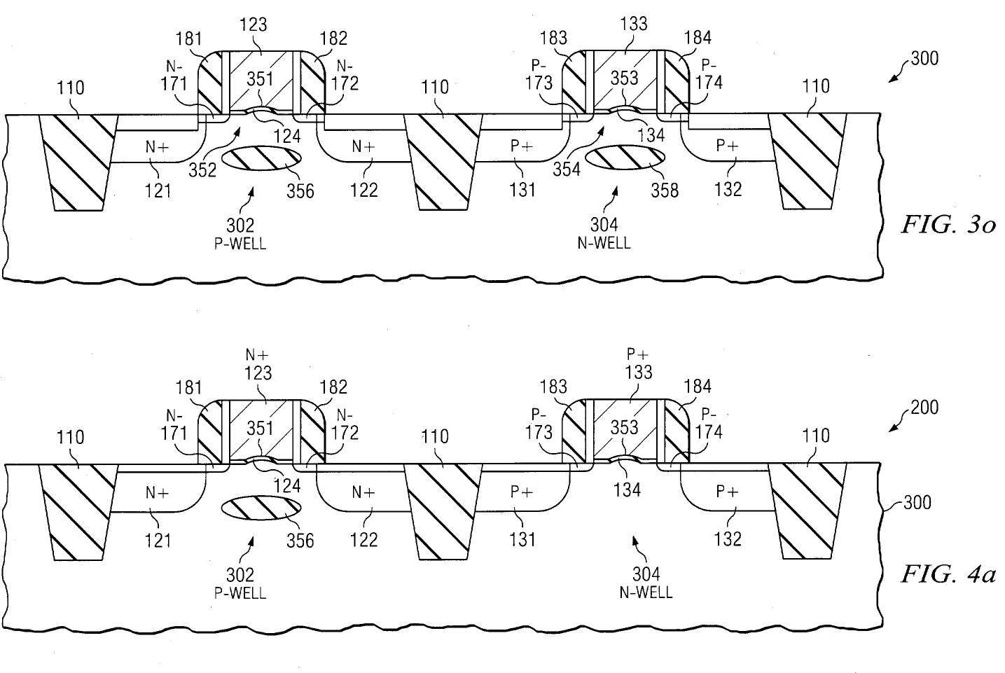

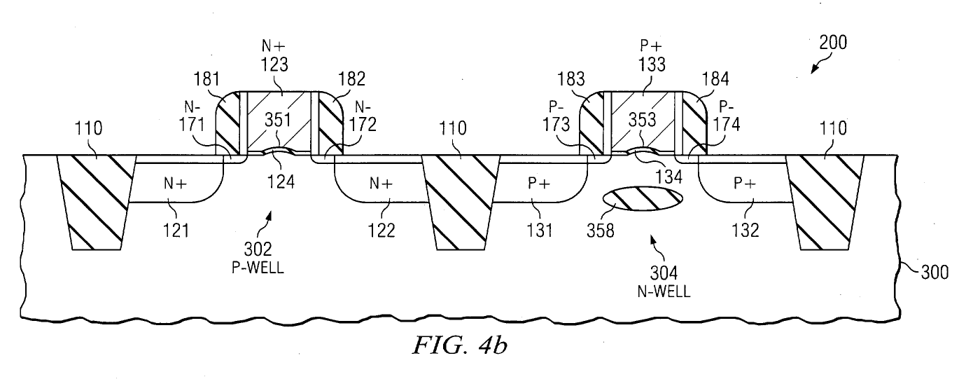

In FIGS. 3g and 3h, oxide regions 356 and 358 are formed, respectively, in semiconductor regions 302 and 304. In an alternative embodiment of CMOS device 200, only pocket of oxygen 346 is created in semiconductor region 302, and consequently only oxide region 356 is formed in semiconductor region 302 as shown in FIG. 4a. To create only pocket of oxygen 346 but not pocket of oxygen 348, areas generally above semiconductor region 304 can be covered with photoresist during the ion implantation process. In another alternative embodiment of CMOS device 200, only pocket of oxygen 348 is created in semiconductor regions 304, and consequently only oxide region 358 is formed in semiconductor region 304, as shown in FIG. 4b. To create only pocket of oxygen 348 but not pocket of oxygen 346, areas generally above semiconductor region 302 can be covered with photoresist during the ion implantation process.

FIGS. 3i to 3l generally depict a preferred manufacturing process for forming the gates of the MOSFETs in CMOS device 200.

FIG. 3i shows that thin layers of high quality gate dielectric 124 and 134 are formed, respectively, on top surface 351 and top surface 353. High quality gate dielectric 124 and 134 can be thin layers of silicon dioxide. The thin layers of silicon dioxide can be formed in an oxidation process (e.g., a thermal oxidation process) or deposited in a chemical vapor deposition process. While silicon dioxide is the preferred gate oxide, other gate oxides, whether currently known or subsequently developed, could be employed in embodiments of the present invention as well.

FIG. 3j shows that a layer of poly-silicon 360 is deposited on top of silicon substrate 300. The layer of poly-silicon 360 can cover the surface areas on top of high quality gate dielectric 124 and 134. The layer of poly-silicon 360 can also cover all of the surface areas on top of silicon substrate 300 (as shown in FIG. 3j). Poly-silicon 360 is preferably deposited using low pressure chemical vapor deposition (LPCVD).

FIG. 3k shows that the top surface of silicon substrate 300 is flattened in a flattening process. The flattening process is preferably a CMP process. After the flattening process, the general structures for gates 123 and 133 are defined. Note that, as illustrated in FIG. 3k, a top portion of silicon nitride layer 330 and of oxide spacers 341, 342, 343, and 344 is also preferably removed along with the top portion of poly-silicon layer 360, resulting in a planar top surface. The poly-silicon for gates 123 and 133 can be doped with n-type dopants to make the gates more conductive.

FIG. 3l shows CMOS device 200 after silicon nitride layer 330 and the oxide spacers (i.e., 341, 342, 343, and 344) are (substantially) completely removed. Silicon nitride layer 330 and the oxide spacers can be removed using a selective etching process that has a relative low etching rate for poly-silicon materials. Example of such an etch process would include, for instance, a plasma (dry) etch, or a wet etch using H₃PO₄. Other etch processes will be apparent to one of skill in the art or can be ascertained with routine experimentation.

FIG. 3m shows that some regions of MOSFETs between the gate and the source region and between the gate and the drain region are lightly doped. More specifically, regions 171 and 172 are lightly doped with n-type dopant, and regions 173 and 174 are lightly doped with p-type dopant. As shown in the figure, region 171 is between gate 123 and the source region (or the drain region) and region 172 is between gate 123 and the drain region (or the source region). Also in the figure, region 173 is between gate 133 and the source region (or the drain region) and region 174 is between gate 133 and the drain region (or the source region). These lightly doped regions, commonly referred to as a lightly doped drain (LDD) region, are preferable but are not necessary to the present invention. In other embodiments of the invention, various doping profiles may be employed, including one or more LDD regions and one or more heavily doped regions of different impurity concentrations and profiles for improved junction grading and short channel effects. Additionally, while the N-channel and P-channel MOSFETs illustrated in the preferred embodiments have symmetrical doped regions, in other embodiments the doped region of one or both transistors could be asymmetric.

FIG. 3n shows that spacers are formed in the vicinity of the gates of the MOSFETs in CMOS device 200. More specifically, spacers 181 and 182 are formed in the vicinity of the gate 123 for N-channel MOSFET 220, and spacers 183 and 184 are formed in the vicinity of the gate 133 for P-channel MOSFET 230. These spacers are preferably formed by the deposition of appropriately selected dielectric layers, such as an oxide layer or nitride layer, or, in the illustrated embodiment, an oxide and nitride layer, and anisotropically etching the layers to form the spacer features, as is well known in the art.

FIG. 3o shows the salicide formation process for the gates, sources, and drains of the MOSFETs in CMOS device 200. The salicide formation process (i.e., self-aligned silicide formation process) preferably includes two steps. In the first step, refectory metals (e.g., Ti, Co, Ni, W, Ta) are deposited on top areas of the gates, sources, and drains of the MOSFETs in CMOS device 200. In the second step, the MOSFETs in CMOS device 200 are subjected to an annealing process. During the annealing process, the deposited refectory metal reacts with the silicon in the gates, sources, and drains of the MOSFETs and forms metal silicide on top of the gates, sources, and drains. One of the advantages of the metal silicide is that ohmic contacts to the gates, sources, and drains can be more easily formed. While preferable, the silicide or salicide formation process is not necessary to the present invention.

In the gates formation process as depicted in FIGS. 3i to 3l, the source and drain regions (i.e., 121, 122, 131, and 132) have already been defined in the process as shown in FIG. 3c and FIG. 3d. That is, the source and drain regions (i.e., 121, 122, 131, and 132) are formed before the gates (i.e., 123 and 133) are formed. In an alternative embodiment, the gates (i.e., 123 and 133) can be formed after the source and drain regions (i.e., 121, 122, 131, and 132) are formed. More specifically, if the source and drain regions (i.e., 121, 122, 131, and 132) are not formed in the process as shown in FIG. 3c and FIG. 3d, the source and drain regions can be formed after the formation of the spacers (i.e., 181, 182, 183, and 184) as shown in FIG. 3n. Source and drain regions, 121 and 122, can be formed by heavily doping selected areas with n-type dopant; source and drain regions, 131 and 132, can be formed by heavily doping selected areas with p-type dopant. During these doping processes, areas that are not selected for doping can be protected with photoresist. In yet another embodiment, polysilicon gates 123 and 133 can be formed first using known photolithographic techniques and source and drain regions 121, 122, 131, and 132 can be subsequently formed. In these embodiments, which eliminate the need for channel masks 314 and 316, using gates 123 and 133 (preferably in conjunction with appropriately formed sidewall spacers) can allow for a self-aligned implantation of the source and drain regions.

The scope of the present application is not intended to be limited to the particular embodiments of the circuit, process, machine, manufacture, means, methods and steps described in the specification. As one of ordinary skill in the art will readily appreciate from the disclosure of the present invention, circuits, components, processes, machines, manufacture, means, methods, or steps, presently existing or later to be developed, that perform substantially the same function or achieve substantially the same result as the corresponding embodiments described herein may be utilized according to the present invention. For instance, although the preferred embodiments were described in the context of CMOS devices, the teachings of the present invention are equally applicable to NMOS devices and PMOS devices. Additionally, substrate 300, while described as a silicon substrate, could alternatively be a silicon-on-insulator (SOI) substrate, or any other substrate that provides sufficient mechanical and electrical properties for the formation of active devices thereon. Although the illustrated embodiments use transistors formed on the surface of the substrate, the present invention is equally applicable to vertical gate transistors, such as transistors formed on the sidewall of a trench formed within the substrate. Other transistor structures than those illustrated may also benefit from the advantages of the present invention. Accordingly, the appended claims are intended to include within their scope such circuits, components, processes, machines, manufacture, means, methods, or steps.

1. A transistor device comprising:
a semiconductor region having a top surface;
a source region in the semiconductor region;
a drain region in the semiconductor region;
a channel region in the semiconductor region between the source region and the drain region;
an impurity region within the channel region and spaced from the top surface, the impurity region laterally spaced from the source and drain regions;
a gate overlying the channel region; and
a gate dielectric between the gate and the channel region.

2. The device of claim 1 wherein the semiconductor region comprises a region of monocrystalline silicon.

3. The device of claim 2 wherein the semiconductor region comprises a silicon substrate.

4. The device of claim 1 wherein the source and drain regions extend into the semiconductor region a first distance, and wherein the impurity region is spaced from the top surface by a distance less than the first distance.

5. The device of claim 1 wherein the gate dielectric comprises silicon dioxide.

6. The device of claim 1 wherein the impurity region comprises a region of an implanted oxygen bearing species in the channel region.

7. The device of claim 1 wherein the channel region comprises a strained channel region.

8. The device of claim 1 and further comprising:
a first sidewall spacer adjacent a first sidewall of the gate;
a second sidewall spacer adjacent a second sidewall of the gate;
a lightly doped drain region within the semiconductor region adjacent the drain region, the lightly doped drain region disposed beneath the first sidewall; and
a lightly doped source region within the semiconductor region adjacent the source region, the lightly doped source region disposed beneath the second sidewall.

9. The device of claim 1 and further comprising a second transistor, the second transistor including:
a second source region in the semiconductor region;
a second drain region in the semiconductor region;
a second channel region in the semiconductor region between the second source region and the second drain region;
a second gate overlying the channel region; and
a second gate dielectric between the gate and the channel region.

10. The device of claim 9 further comprising a second impurity region within the second channel region and spaced from the top surface, the second impurity region laterally spaced from the second source region and the second drain region.

11. The device of claim 9 wherein the second transistor does not include an impurity region within the second channel region.

12. The device of claim 9 wherein the second transistor device comprises an n-channel transistor.

13. A method of forming a transistor device, the method comprising:
providing a semiconductor region having a top surface;
forming source and drain regions in the semiconductor region, the source region being spaced from the drain region by a channel region;
forming an oxide region within the channel region and spaced from the top surface; and
forming a gate overlying and insulated from the channel region.

14. The method of claim 13 wherein the oxide region is formed before forming the source and drain regions.

15. The method of claim 13 wherein the oxide region is formed after forming the source and drain regions.

16. The method of claim 13 wherein forming an oxide region comprises implanting an oxygen bearing species.

17. The method of claim 16 wherein the oxygen bearing species comprises O₂.

18. The method of claim 16 wherein forming an oxide region further comprises annealing the transistor device after implanting the oxygen bearing species.

19. The method of claim 13 wherein the step of forming source and drain regions includes forming lightly doped source and drain regions.

20. The method of claim 13 wherein the step of forming source and drain regions includes forming heavily doped source and drain regions.

21. The method of claim 13 wherein forming the gate includes forming a gate dielectric between the gate and the channel region.

22. The method of claim 13 wherein the gate dielectric comprises silicon dioxide.

23. The method of claim 21 wherein forming the gate includes forming a poly-silicon layer on top of the gate dielectric.

24. The method of claim 13 wherein the semiconductor region comprises a silicon substrate.

25. The method of claim 13 further comprising:
forming a first sidewall spacer adjacent a first sidewall of the gate;
forming a second sidewall spacer adjacent a second sidewall of the gate;
forming a lightly doped drain region within the semiconductor region adjacent the drain region, the lightly doped drain region disposed beneath the first sidewall; and
forming a lightly doped source region within the semiconductor region adjacent the source region, the lightly doped source region disposed beneath the second sidewall.

26. A method of manufacturing a CMOS device, the CMOS device including a P-channel MOSFET and an N-channel MOSFET, the method comprising:
providing a semiconductor region having a top surface;
forming source and drain regions for the P-channel MOSFET in a first part of the semiconductor region, the source region being spaced from the drain region by a P-channel region;
forming source and drain regions for the N-channel MOSFET in a second part of the semiconductor region, the source region being spaced from the drain region by an N-channel region;
forming at least one oxide region in the semiconductor region spaced from the top surface; and
forming a gate for the P-channel MOSFET and a gate for the N-channel MOSFET, the gate for the P-channel MOSFET overlying and insulated from the P-channel region, and the gate for the N-channel MOSFET overlying and insulated from the N-channel region.

27. The method of claim 26 wherein forming at least one oxide region includes forming an oxide region between the source and drain regions for the P-channel MOSFET.

28. The method of claim 26 wherein forming at least one oxide region includes forming an oxide region between the source and drain regions for the N-channel MOSFET.

29. The method of claim 26 wherein forming at least one oxide region includes:
forming a first oxide region between the source and drain regions for the P-channel MOSFET; and
forming a second oxide region between the source and drain regions for the N-channel MOSFET.
